(19) United States
(12) Patent Application Publication
(10) Pub. No.: US 2005/0054205 A1
(43) Pub. Date: Mar. 10, 2005

(54) Mask trimming apparatus and mask trimming method

(76) Inventors: Junichi Tanaka, Hachioji (JP); Hideyuki Yamamoto, Kudamatsu (JP); Akira Kagoshima, Kudamatsu (JP); Daisuke Shiraishi, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/790,212

(22) Filed: Mar. 2, 2004

(30) Foreign Application Priority Data
Sep. 5, 2003 (JP) 2003-314141

(51) Int. Cl. H01L 21/302; H01L 21/461

(52) U.S. Cl. 438/706

(57) ABSTRACT

A plasma etching apparatus and method are provided to obtain an accurate dimension after trimming based on an amount of roughness of a mask edge or an amount of radicals in plasma. A wafer on the surface of which a desirably patterned mask for etching is formed is processed in a plasma etching process chamber and the mask is trim-treated by plasma etching so as to reduce the patterned mask width. The apparatus includes a plasma monitor for measuring an amount of radicals in the plasma process chamber, and a trimming condition calculator for calculating a time required for the trimming to obtain a desired mask width, based on a pre-measured width dimension of the patterned mask and a pre-measured amount of roughness of a mask edge and the radical amount measured by the plasma monitor. The trimming is performed for the time calculated by the trimming condition calculator.

### BACKGROUND OF THE INVENTION

The present invention relates to mask trimming apparatus and method and more particularly, to mask trimming apparatus and method capable of obtaining a necessary amount of trimming.

A plasma etching apparatus used for fabrication process of semiconductor devices etches polysilicon or the like on a wafer by using, as a mask, resist formed into a predetermined pattern by means of a lithography apparatus, thereby forming gate electrodes of a CMOS device, for instance.

In plasma etching, a mechanism called RIE (reactive ion etching) utilizing ions and radicals in plasma is used to work the wafer. In the RIE, the wafer is applied with a bias voltage to attract ions representing charged particles toward the wafer so that an ion current may be accelerated in a direction vertical to the wafer. As a result, anisotropic etching can be carried out. In the anisotropic etching, etching can proceed in only a direction in which a mask pattern is transcribed vertically and therefore, a desired etching result corresponding to the mask pattern can be obtained.

On the other hand, the radicals in plasma are not electrified, so that they are unaffected by the bias to incide or come into the wafer isotropically. As a result, isotropic etching can proceed.

In other words, ions and radicals coexist in plasma in the case of the RIE and the anisotropic etching and isotropic etching can proceed simultaneously. For example, in case the isotropic etching is excessively strong, the sidewall of a gate electrode expected to be shaved vertically will be scooped out. Conversely, if the isotropic etching is excessively weak, substances such as reaction products will deposit on the sidewall, which sidewall will gradually be pushed out to take a tapered form.

An optimum shape of the gate electrode can be obtained by skillfully preserving the balance between the anisotropic etching and the isotropic etching. When it comes to forming a gate electrode having as vertical a shape as possible, the isotropic etching is also caused to proceed in etching and the gate width becomes smaller. In other words, a gate width dimensionally equal to a mask width is not always obtained and the gate width to be formed through etching changes with a change in plasma status.

Incidentally, with recent advance in dimensional reduction of semiconductor devices, permissible errors in work dimension required of the plasma etching apparatus have also been reduced. For example, in case of working a gate electrode, the gate width determining the performance of a device (the gate width dimension is managed by calling it CD (critical dimension)) and for a forefront device, the gate width is less than 30 nm and the tolerance of dispersion of CD is not greater than several nanometers.

Patterning in such a dimension is not possible with the existing lithography apparatus and to overcome this problem, a resist-trimming method has been employed.

Trimming of a resist mask will be explained by making reference to side sectional views of FIGS. 9A to 9C in which a patterned wafer is viewed by sectioning it vertically to a direction of the wafer surface and mask pattern. In the figures, reference numeral 21 designates a wafer (crystalline silicon), 22 a gate insulating film, 23 a gate electrode made of polysilicon or the like, and 24, 24b and 24c resist masks. In particular, designated by 24 is a resist mask before trimming, by 24b is a resist mask after trimming and by 24c is an etching mask after trimming. It will be appreciated that in trimming, the wafer 21 is carried on a specimen stage not shown. Then, the specimen stage is applied with a high-frequency bias for attracting ions in plasma.

In etching based on a treatment of trimming the resist mask, the resist mask patterned as shown in FIG. 9A, for instance, is thinned by isotropic etching as shown in FIG. 9B and the underlying polysilicon is worked by using the mask further thinned as shown in FIG. 9C.

The technique as above can provide, through the trimming method, a mask pattern thinner than the thinning limit of a mask pattern which can be prepared by the lithography technique. Typically, in this type of trimming, the geometrical dimension of a resist mask obtained through patterning based on the lithography technique is measured and then an amount of trimming is determined from a difference between the thus measured dimension and a target gate dimension. The trimming amount is directly proportional to a treatment time for execution of the trimming treatment. Accordingly, by performing the trimming treatment for a trimming time corresponding to the trimming amount, a mask pattern of a desired dimension can be obtained. In the present specification, an amount of trimming per unit time is called a trimming rate.

Incidentally, in the lithography apparatus, the conventional lithography using a KrF excimer laser or F2 excimer laser has been shifting to lithography using an ArF excimer for the purpose of patterning much thinner gate widths. A resist mask made of a resist material for use in the ArF lithography has an edge portion of large roughness and as the gate width reduces, the dimension of the edge roughness amounts to a value which cannot be negligible as compared to the gate width.

For the reasons as above, in the trimming treatment using the etching apparatus, alleviation of the edge roughness by the action of isotropic etching is required in addition to thinning of the mask dimension.

An edge roughness alleviating treatment will be described by making reference to FIGS. 10A and 10B. A mask before trimming is illustrated in top view form in FIG. 10A and a mask after trimming is illustrated in top view form in FIG. 10B. As will be seen from FIG. 10B, the edge roughness is alleviated after the trimming and the mask pattern is more smoothed. It will also be seen from the figures that the dimension to be trimmed includes a reduction in dimension due to removal of the edge roughness. When the edge roughness is several nanometers, an unevenness of dispersion of CD permissible for etching work approximately equally amounts to the dimension of the edge roughness. Since the edge roughness portion contours a bulky mask portion and is irregular or rugged in shape, the trimming rate differs depending on the degree of the edge roughness. For this reason, in order to set a trimming time necessary for obtaining a desired trimming amount, the degree of edge roughness must be taken into account. The alleviation of edge roughness by trimming is disclosed in, for example, Shabid Rauf et al “Journal of Vacuum Science and Technology B”, Vol. 21, No. 2, pp. 655-659, Mar/Apr, 2003.

### SUMMARY OF THE INVENTION

The Rauf et al article discloses that alleviation of the edge roughness by the action of trimming can be promoted in proportion to the time lapse. But it fails to disclose a trimming method for obtaining an accurate dimension after trimming.

The trimming rate in plasma etching mainly depends on an amount of radicals in plasma. The radical amount, however, changes with a status of the wall of a plasma treatment chamber even when the recipe is intact. The wall status is caused to change because reaction products due to an etching reaction will deposit on the wall or the status of the surface of quartz or metallic parts exposed to plasma will change and as a result the deposition rate or recombination probability of radicals changes with time.

In addition, as described previously, the trimming rate in the plasma etching differs depending on the degree of edge roughness.

Accordingly, for the purpose of calculating an accurate trimming amount or trimming time, it is necessary to accurately know the degree of edge roughness and the radical amount in plasma at the time of trimming. The present invention is made in the light of the above problems and an object of the invention is to provide plasma treatment apparatus and method capable of obtaining an accurate dimension after trimming on the basis of an amount of roughness of a mask edge or an amount of radicals in plasma.

To accomplish the above object, according to one feature of the invention, in an etching apparatus functioning to process a wafer having on its surface a desirably patterned mask for etching, in a plasma etching treatment chamber, and trim-treat the mask under the etching action by plasma so as to reduce the width of the patterned mask, the etching apparatus comprises a plasma monitor for measuring an amount of radicals in the plasma treatment chamber, and trimming condition calculating means for calculating a condition such as a time required for the trimming treatment to obtain a desired mask width, on the basis of a precedently measured width dimension of the patterned mask and a precedently measured amount of roughness of a mask edge as well as the amount of radicals measured by the plasma monitor, wherein the trimming treatment is carried out for the trimming condition calculated by the trimming condition calculating means.

With the above construction, the present invention can provide plasma treatment apparatus and method capable of obtaining an accurate dimension after trimming on the basis of the roughness amount of a mask edge and the radical amount in plasma.

Other objects, features and advantages of the invention will become apparent from the following description of the embodiments of the invention taken in conjunction with the accompanying drawings.

### BRIEF DESCRIPTION OF THE DRAWINGS

FIG. 1 is a block diagram useful to explain the system construction of an etching apparatus having a trimming treatment function.

FIG. 2 is a flowchart useful to explain a trimming method.

FIG. 3 is a top view of part of mask pattern on a wafer cut out before a trimming treatment.

FIG. 4 is a graph useful to explain a change in maximum width of the mask during trimming.

FIGS. 5A to 5C are diagrams useful to explain trimming of an edge roughness portion of the mask.

FIG. 6 is a diagram useful to explain an amount of edge roughness.

FIG. 7 is a graph useful to explain the relation between the trimming amount of mask proper and the treatment time in trimming step.

FIG. 8 is a graph showing a spectrum of plasma emission.

FIGS. 9A to 9C are side sectional views useful in explaining trimming of a resist mask by sectioning a patterned wafer in a direction vertical to the wafer surface and the mask patterning direction.

FIGS. 10A and 10B are diagrams useful to explain an edge roughness alleviating treatment.

### DETAILED DESCRIPTION OF THE EMBODIMENTS

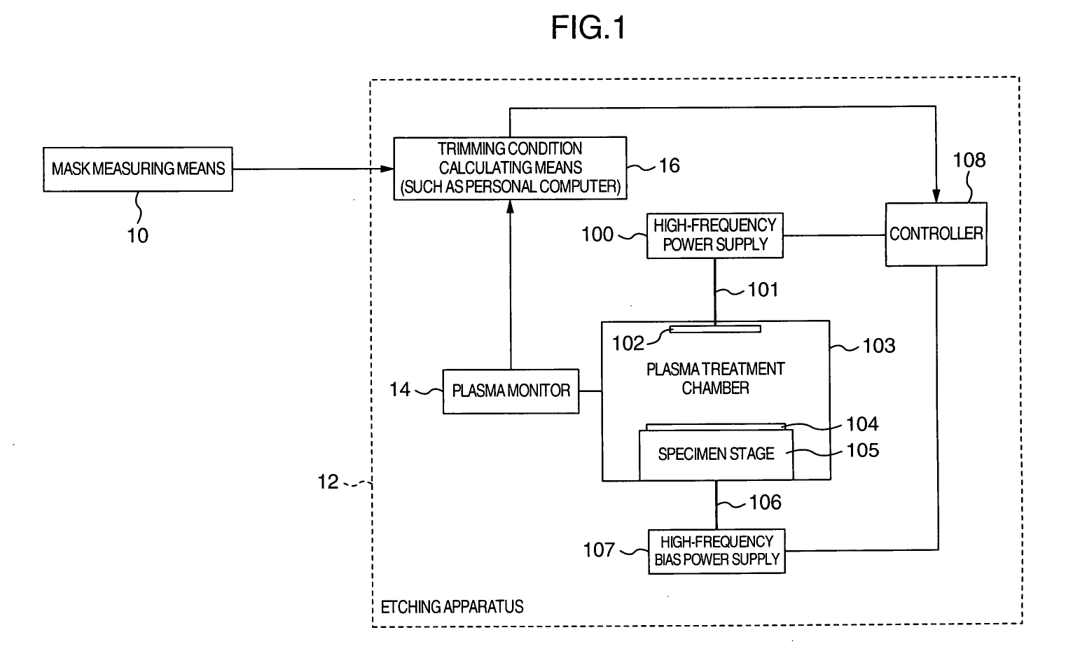

Preferred embodiments of the invention will now be described with reference to the accompanying drawings. Referring first to FIG. 1, the system construction of an etching apparatus 12 having a trimming treatment function will be described. In FIG. 1, high-frequency power generated in a high-frequency power supply 100 is fed to an antenna 102 by way of a high-frequency transmission path 101 and radiated to the interior of a plasma treatment chamber 103. An etching gas is admitted to the interior of the plasma treatment chamber 103 by means of a gas supply means, not shown, and the interior is maintained at a low pressure by means of a gas evacuation means such as a turbo molecular pump similarly not shown.

The high-frequency power radiated from the antenna 102 generates plasma inside the plasma treatment chamber 100 maintained at the low pressure. A wafer 104 is carried on a specimen stage 105. High-frequency power generated by a high-frequency bias power supply 107 is applied through a high-frequency transmission path 106 to the specimen stage to apply it with bias power, so that ions in the plasma can be attracted toward the wafer.

A plasma monitor 14, for example, an optical emission spectrometer, measures an amount of radicals in the plasma. The emission spectrometer is optimally used as the plasma monitor 14 but alternatively, electrical characteristics of plasma such as plasma impedance may be measured and an amount of radicals may be presumed from the measured electrical characteristics.

A trimming condition calculating means 16 receives measurement results of mask width and mask edge roughness for the wafer 104 from a mask measuring means 10 typically installed externally of the etching apparatus. The mask measuring means 10 is an apparatus capable of measuring the mask width and mask edge roughness, such as for example an SEM (scanning electron microscope), an AFM (atomic force microscope) or a scatterometry measuring apparatus. More preferably, the mask measuring means 10 may be built in the etching apparatus.

With the wafer 104 mounted on the specimen stage 105, a controller 108 for controlling the etching apparatus permits the etching gas to be supplied into the plasma treatment chamber and permits the high-frequency power supply 100 to supply the high-frequency power when the pressure inside the plasma treatment chamber is stabilized to a predetermined value, thereby generating plasma. Subsequently, the controller 108 permits the high-frequency power supply 107 to apply the bias power to thereby start a process of trimming the wafer 104.

When the treatment of the wafer 104 is started, the plasma monitor 14 monitors the radical status in the plasma to transmit a measured amount of radicals to the trimming condition calculating means 16.

From the received radical amount as well as the mask width and mask edge roughness amount, the trimming condition calculating means calculates a trimming time necessary for obtaining a desired mask width and transmits the trimming time to the controller 108. After the calculated trimming time has elapsed, the controller 108 stops the trimming treatment.

After the desired mask width has been obtained, the wafer 104 may be taken out so that it may be treated in a different etching treatment chamber but for more efficient etching work, the controller 108 may continue the etching treatment after completion of the trimming treatment until etching work of gate electrodes is completed. In the present embodiment, the trimming condition calculating means is disposed in the etching apparatus but alternatively, it may be installed externally through the medium of a LAN, for instance.

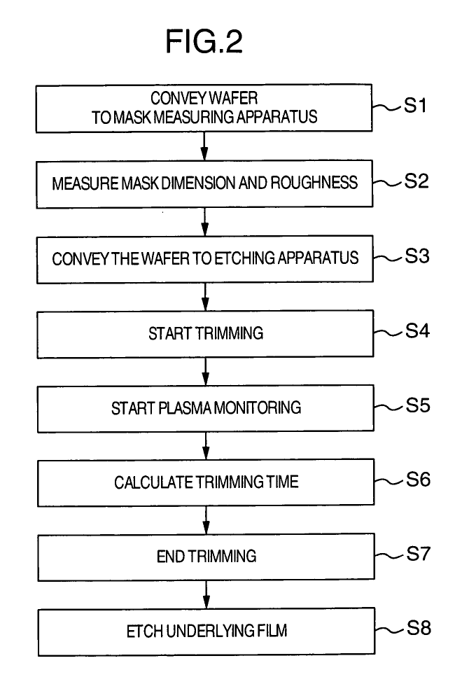

Referring to FIG. 2, there is illustrated a flowchart of an etching method utilizing the system shown in FIG. 1. Firstly, a wafer having a patterned mask on its surface is conveyed to the mask measuring apparatus and a width dimension of the patterned mask and an amount of roughness of a mask edge are measured (steps 1 and 2). Subsequently, the wafer for which measurement is completed is conveyed into the etching apparatus and trimming (etching) is started (steps 3 and 4). At that time, monitoring by the plasma monitor is started to measure an amount of radicals or an amount of ions in the plasma treatment chamber (step 5). Then, the trimming condition calculating means acquires the measured mask width dimension and mask edge roughness amount as well as the radical amount or ion amount in the plasma treatment chamber and on the basis of the acquired mask width dimension, mask edge roughness amount as well as the radical amount or ion amount in the plasma treatment chamber, calculates a trimming time (etching time) necessary for the mask dimension to reach a target value as will be described later (step 6). The etching apparatus 12 acquires the trimming time calculated as above and ends the trimming when the trimming time has expired (step 7). With the trimming ended, an underlying film (such as a polysilicon film constituting gate electrodes) is etched by utilizing the mask for which the trimming is ended (step 8).

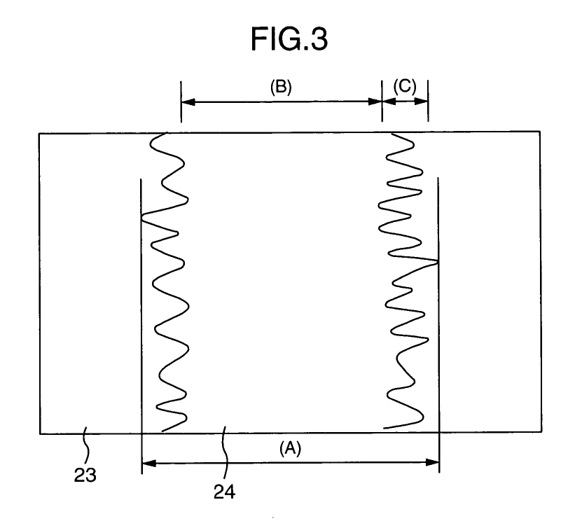

Part of a mask pattern on the wafer before the trimming treatment is cut off as shown in top view form in FIG. 3. In the figure, polysilicon designated by reference numeral 23 is formed on the wafer not shown and utilized for, for example, gate electrodes of FET's formed on the wafer. Designated by 24 is the mask formed on the polysilicon 23. The mask has a maximum width of A, a width of B of mask proper and an edge roughness portion C.

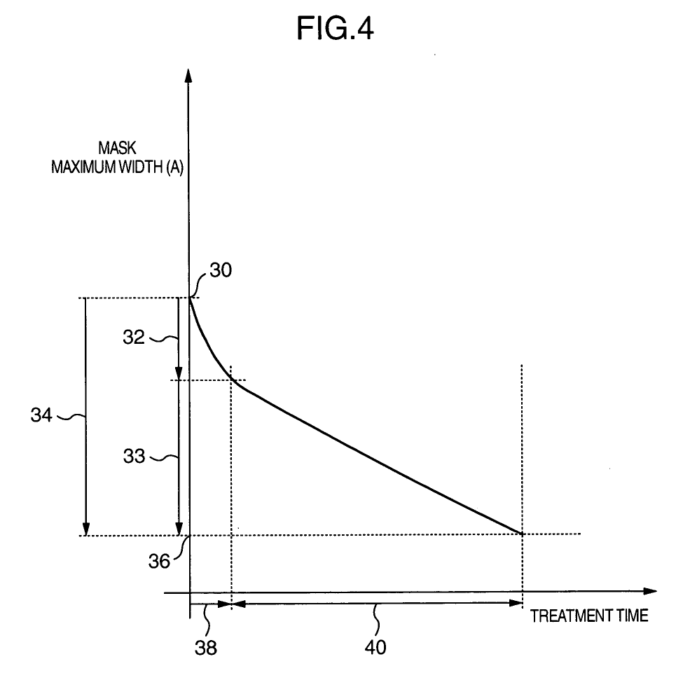

The maximum width of the mask changes during trimming as will be described with reference to graphical representation of FIG. 4. Indicated in the graph are an initial value 30 of the mask maximum width, a trimming amount 32 of the mask edge roughness portion, a trimming amount 33 of the mask proper, a total trimming amount 34 of the mask and a target value 36 of the mask width. Also indicated are an edge roughness portion trimming time 38 and a mask proper trimming time 40.

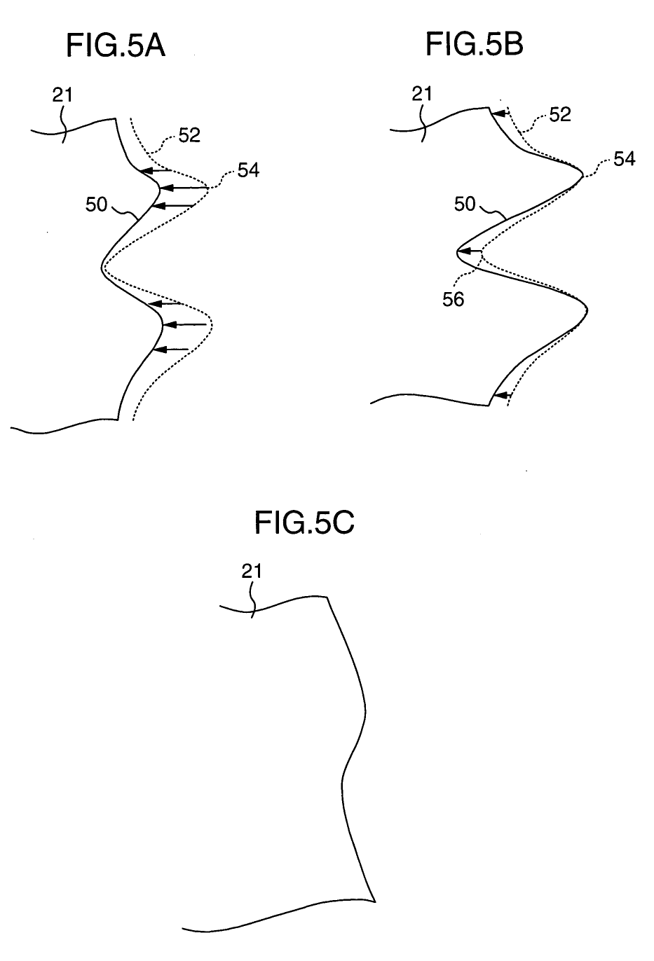

Referring to FIGS. 5A to 5C, trimming of the edge roughness portion of mask will be described. FIG. 5A is useful to explain the trimming by radicals. Radicals do not have directivity in contrast to ions. Accordingly, the radicals are liable to impinge upon a fore end 54 of the roughness and the fore end 54 is scraped off at a high rate (etching rate). As a result, a mask edge 52 before trimming is much scraped off in the vicinity of the fore end and a mask edge 50 shaped as illustrated is formed after trimming. This alleviates the mask edge roughness.

FIG. 5B is useful to explain the trimming by ions. Ions are accelerated vertically to the sheet of drawing by the high-frequency bias applied to the specimen stage carrying the wafer while impinging upon the sidewall of the edge roughness portion.

Ions impinging upon the fore end 54 of roughness are reflected thereat and there is a small possibility that the ions will again impinge upon the mask. Accordingly, the fore end of roughness is etched by the ions by a small amount. On the other hand, ions incident upon a valley 56 of roughness are reflected thereat and again impinge upon the nearby sidewall to etch the mask sidewall. Accordingly, when ions dominate, the valley is prone to be etched. It is to be noted that the etching rate by ions is smaller than that by radicals and can be negligible.

FIG. 5C is useful to explain trimming of the edge roughness which is smoother than that in FIG. 5B or 5C. The characteristics as shown in FIGS. 5B and 5C do not appear in this case and characteristics resembling those of mask proper trimming in FIG. 4 are obtained.

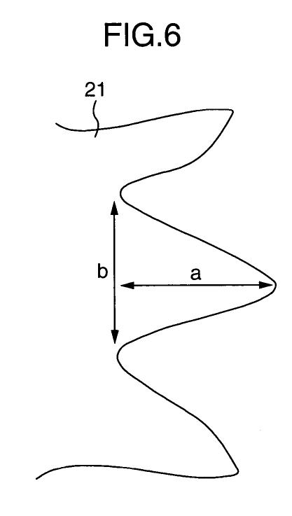

Turning to FIG. 6, the edge roughness amount (the amount indicative of the degree of edge roughness) will be explained. As described previously, the etching amount in the edge roughness portion is greatly affected by the degree of unevenness or corrugation in the roughness portion. Therefore, the edge roughness amount to be measured by the mask measuring means must be an amount indicative of the degree of unevenness in the roughness.

Accordingly, the edge roughness amount can be expressed by, for example, equation (1), that is, by the aspect ratio:
(edge roughness amount)=a/b (1)
where a represents a protrusion amount of mask edge 52 and b represents a protrusion width of mask edge 52. As the edge roughness amount increases, the edge roughness portion becomes rougher pursuant to equation (1).

Incidentally, by monitoring an uneven or undulated form of the edge roughness portion and Fourier-transforming the monitored uneven form, a spatial frequency of the uneven or undulated form can be obtained. Then, either a representative or frequency distribution of the spatial frequency can be used as the roughness amount. In an alternative, the fractal dimension can be calculated to provide an amount of roughness.

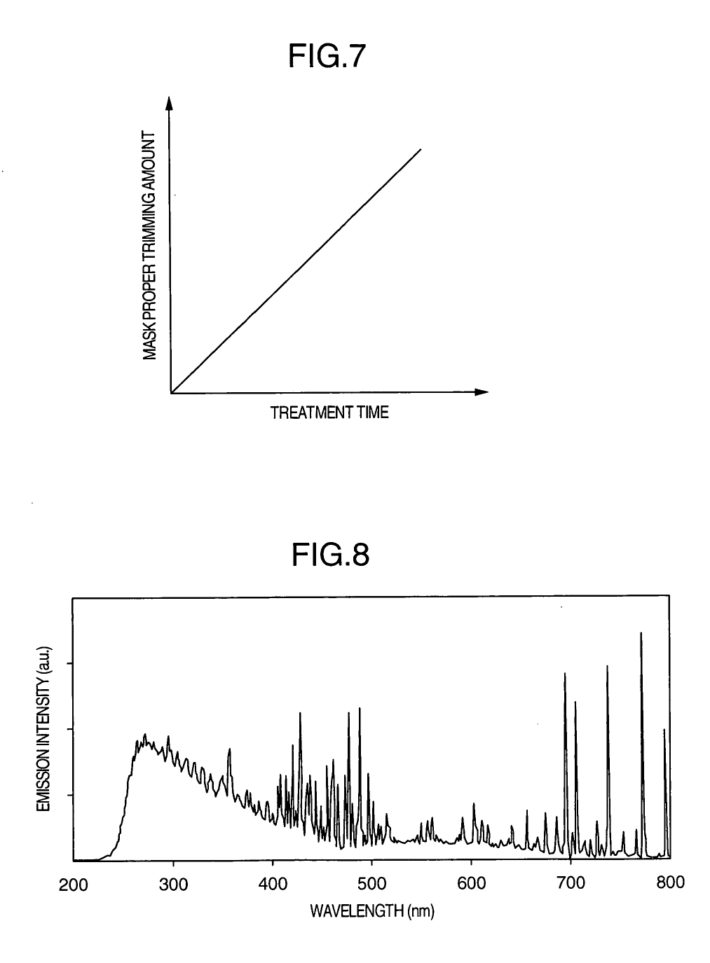

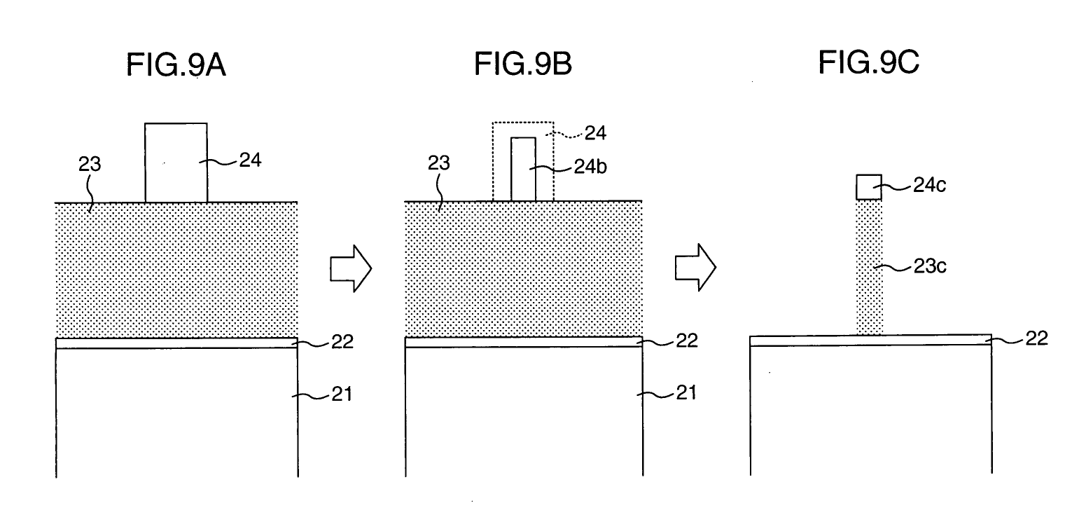

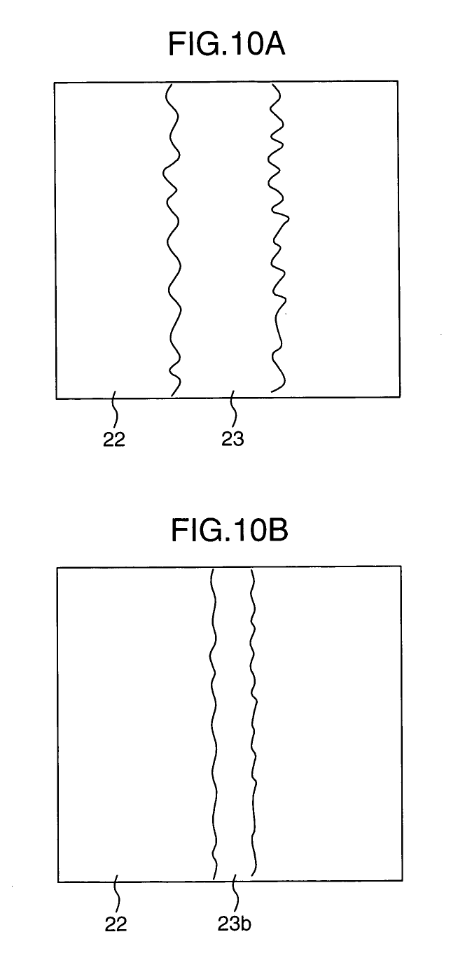

Referring to FIG. 7, there is illustrated a graph useful to explain the relation between the mask proper trimming amount and the treatment time in trimming step. As shown in the figure, the mask proper trimming amount is directly proportional to the trimming time.

Next, the process by the trimming condition calculating means 16 will be described. Firstly, the trimming amount of edge roughness portion shown in FIG. 4 can be expressed by equation (2):
(edge roughness trimming amount 32)=F(edge roughness, radical amount, ion amount) (2)
Further, the edge roughness trimming time 38 required for obtaining the edge roughness trimming amount 32 can be expressed by equation (3):
(edge roughness trimming time 38)=G(edge roughness, radical amount, ion amount) (3)

On the other hand, the mask proper trimming amount is directly proportional to the trimming time as shown in FIG. 7. Therefore, equation (4) stands:
(mask proper trimming amount)=K×(mask proper trimming time) (4)
where K indicates the gradient of straight line shown in FIG. 7 representing the trimming rate of the mask proper. It will be appreciated that K is also a function of the radical amount and ion amount.

Accordingly, the trimming time (total trimming time) can be determined pursuant to equation (5):
(trimming time)=G(edge roughness, radical amount, ion amount)+(target value after trimming−F(edge roughness, radical amount, ion amount))/K (5)

Referring now to FIG. 8, a spectrum of plasma emission is graphically illustrated. When the emission spectrometer is used as the plasma monitor, the radical amount or ion amount can be calculated from the plasma emission spectrum as shown in FIG. 8. The emission spectrum has peaks corresponding to characteristic wavelengths generated by radicals or ions and on the basis of the height of peaks, amounts of radicals or amounts of ions can be measured. Since the emission spectrum contains information of many radicals and besides not a single but many radicals contribute to the trimming, values obtained by calculating plural peaks can be determined as the radical amounts or ion amounts contributing to the trimming.

In addition, a principal component score, for instance, which is obtained by analyzing the emission spectrum through a multivariate analysis such as principal component analysis or PLS analysis, can be used to provide amounts representing the radical or ion amounts. When the principal component analysis is used, the aforementioned functions F, G and K can be generated through a multiple regression analysis in which a principal component score is calculated from an emission spectrum obtained through a pre-experiment to provide an explanatory variate and an actually measured trimming amount is used as an objective variate.

As described above, according to the present embodiment, on the basis of the width dimension of mask and the roughness amount of mask edge measured by the mask measuring means as well as the radical amount and ion amount measured by the plasma monitor, the etching rate for the edge roughness portion and the etching rate for the mask proper are calculated and on the basis of the calculation results, the trimming time can be adjusted such that the trimming amount coincides with a target value. In this procedure, other conditions for the trimming process (the generation amount of radicals or ions) can be controlled.

It should be further understood by those skilled in the art that although the foregoing description has been made on embodiments of the invention, the invention is not limited thereto and various changes and modifications may be made without departing from the spirit of the invention and the scope of the appended claims.

The present application claims priority from Japanese application JP-2003-314141 filed on Sep. 5, 2003, the content of which is hereby incorporated by reference into this application.

1. An etching apparatus functioning to process a wafer having on a surface on which a desirably patterned mask for etching is formed, in a plasma etching process chamber and trim-treat said mask under etching action by plasma so as to reduce the width of said patterned mask, said apparatus comprising:
a plasma monitor for measuring an amount of radicals in said plasma process chamber; and
trimming condition calculating means for calculating a condition required for said trimming treatment to obtain a desired mask width on the basis of a precedently measured width dimension of said patterned mask and a precedently measured amount of roughness of a mask edge as well as the amount of radicals measured by said plasma monitor,
wherein the trimming treatment is carried out for the trimming condition calculated by said trimming condition calculating means.

2. An etching apparatus according to claim 1, wherein continuously to said trimming treatment, a treatment of etching said wafer is performed in said plasma etching process chamber.

3. An etching apparatus according to claim 1, wherein the mask edge roughness amount is calculated on the basis of an aspect ratio of a mask edge roughness portion.

4. An etching apparatus according to claim 1, wherein the edge roughness amount is calculated on the basis of a Fourier frequency of the shape of a mask edge roughness portion.

5. An etching apparatus according to claim 1, wherein an optical emission spectrometer is used as said plasma monitor.

6. An etching apparatus according to claim 1, wherein said required condition is a time required for the trimming treatment.

7. A mask trimming method in which a wafer having on the surface of which a desirably patterned mask for etching is formed is processed in a plasma etching process chamber and thereafter, plasma is generated in said plasma etching process chamber to trim-treat said mask under the etching action by said plasma so as to reduce the width of said patterned mask,
said method comprising the steps of:
measuring an amount of radicals in said plasma process chamber by means of a plasma monitor;
calculating a condition required for said trimming treatment to obtain a desired mask width, on the basis of the amount of radicals measured by said monitor as well as a precedently measured width dimension of said patterned mask and a precedently measured amount of roughness of a mask edge; and
carrying out the trimming treatment for the calculated trimming condition.

8. A mask trimming method according to claim 7, wherein an etching treatment is carried out in said plasma etching process chamber continuously to execution of said mask trimming step.

9. A mask trimming method according to claim 7, wherein said required condition is a time required for the trimming treatment.
